(19) United States
(12) Patent Application Publication
(10) Pub. No.: US 2023/0204821 A1
(43) Pub. Date: Jun. 29, 2023

(54) DEVICE, METHOD AND USE FOR THE COATING OF LENSES

(71) Applicant: Schneider GmbH & Co. KG, Fronhausen (DE)

(72) Inventors: Gunter SCHNEIDER, Marburg (DE); Stephan HUTTENHUIS, Niederweimar (DE); Markus FUHR, Erlensee (DE)

(73) Assignee: Schneider GmbH & Co. KG, Fronhausen (DE)

(21) Appl. No.: 18/119,949

(22) Filed: Mar. 10, 2023

Related U.S. Application Data
(63) Continuation-in-part of application No. 15/736,979, filed on Dec. 15, 2017.

(30) Foreign Application Priority Data
Jun. 16, 2015 (EP) 15001772.1
Jun. 17, 2015 (EP) 15001787.9
Sep. 8, 2015 (EP) 15020153.1

(51) Int. Cl. G02B 1/10; G02B 7/02; G02B 7/00; C23C 14/00; G02B 7/14

(52) U.S. Cl. CPC G02B 1/10; G02B 7/021; G02B 7/003; C23C 14/0036; G02B 7/14

(57) ABSTRACT

A device and a method for the coating of lenses. The lenses which are to be coated are arranged in pairs over parallel tubular targets such that they each overlap both a homogeneous and an inhomogeneous removal region of the target and the lenses rotated so that an especially uniform coating can be achieved.

### CROSS-REFERENCE TO RELATED APPLICATIONS

This application is a continuation-in-part of commonly-owned, co-pending U.S. patent application Ser. No. 15/736,979 filed Dec. 15, 2017, which is a 371 of International Patent Application No. PCT/EP2016/025062 filed Jun. 16, 2016, which claims the benefit of priority to European Patent Application No. 15001772.1 filed Jun. 16, 2015, European Patent Application No. 15020153.1 filed Sep. 8, 2015, and European Patent Application No. 15001787.9 filed Jun. 17, 2015, the contents of which are incorporated herein by reference in their entirety.

### BACKGROUND OF THE INVENTION

### Field of the Invention

The present invention relates to a device for coating of lenses a, a method for coating of lenses, as well as a method of using a tubular target for coating of lenses.

The present invention relates in general to the coating of lenses by sputtering which is also called cathode sputtering. In doing so, atoms are separated from a solid, the so-called target, by the impact of high-energy ions, and pass into a gaseous phase. In particular, the present invention relates to so-called magnetron sputtering in which in addition to an applied electrical field there is also a magnetic field behind the cathode and/or the target.

In practice it is difficult to achieve a uniform coating of the lens which is to be coated, even if the prior art discloses many different devices and methods for sputtering.

### Description of Related Art

German Patent DE 40 10 495 C2 discloses a device for coating of a substrate with materials by sputtering, the substrate being able to rotate around a stationary axis and two targets which are kept tilted to the substrate surface being assigned to the substrate. Here, a uniform coating cannot be achieved or at best can only be achieved with great difficulty.

German Utility Model DE 295 05 497 U1 and corresponding U.S. Pat. Nos. 5,911,861 and 6,123,814 disclose a coating station for coating of lenses by sputtering, the lenses being moved in a planetary arrangement over a flat sputtering source. Here, the construction effort is considerable and the feed of the coating station with the lenses to be coated is complex. Furthermore, an optimum uniform coating cannot be achieved or can only be achieved with great difficulty.

International Patent Application Publication WO 03/023813 A1 discloses an apparatus for coating of lenses by pulse magnetron sputtering, the lenses being moved linearly along the longitudinal extension of two tubular targets which run in parallel, and also rotating in doing so. Here, a uniform coating of the lenses cannot be achieved or can be achieved at best only with great difficulty.

### SUMMARY OF THE INVENTION

The object of the present invention is to provide a device and a method for the coating of lenses, a very uniform coating in particular of curved surfaces of the lenses being enabled with a simple structure and/or with simple feed.

The aforementioned object is achieved by a device and methods as disclosed herein.

According to one aspect of the present invention, the device preferably has an elongated or tubular target and the lens which is to be coated can be rotated around an axis which is stationary relative to the target. In particular, in doing so the lens cannot be moved linearly, but it is preferably a stationary arrangement, the target and the lens preferably rotating each around stationary axes. Thus at low construction effort an especially uniform coating of the lens can be achieved.

According to another aspect of the present invention, the lens which is to be coated is preferably held above a target both in a first, at least essentially homogeneous region and in a second, inhomogeneous region of a rate profile of removal of the target, and is rotated in doing so. Thus, an especially uniform coating in particular of a curved lens surface is enabled.

In particular, the lens which is to be coated is held in one end region or its vicinity over the preferably elongated or tubular target. Thus, an especially good utilization of the delivery rate which is increased just towards the end of the target and thus an improved utilization of the atomized target material can take place.

According to another aspect of the present invention, preferably two elongated and/or tubular, in particular parallel targets are used for coating of curved surfaces of lenses, the lenses being arranged in pairs over the target and, preferably, being rotated around one stationary axis. This enables a simple, compact structure, very uniform coatings of the lenses being attainable.

According to another aspect of the present invention the device preferably comprises one carrier which together with at least two lenses is interchangeable. This enables very simple and prompt feed of the device.

According to another aspect of the present invention which can likewise be implemented independently, preferably one target with an outside diameter which varies over its axial extension or longitudinal extension is used for coating of a lens. Thus, in particular the rate profile can be influenced, in particular made uniform, and/or in particular a very uniform or more uniform coating on the lens or some other coating characteristic on the lens can be achieved or facilitated.

The aforementioned aspects as well as the features and aspects of the present invention which follow from the further description can be implemented independently of one another, but also in any combination.

Further aspects, advantages and features of the present invention will become apparent from the following description of a preferred exemplary embodiment with reference to the accompanying drawings.

### BRIEF DESCRIPTION OF THE DRAWINGS

FIG. 1 shows a schematic section of a device according to the proposal for coating of lenses;

FIG. 2 shows a schematic plan view of the device;

FIG. 3 shows a schematic side view of the device with a schematically indicated rate profile;

FIG. 4 shows a schematic plan view of the device according to FIG. 2, but with alternatively arranged lenses;

FIG. 5 shows a schematic section of the device according to FIG. 1 when inserting a carrier;

FIG. 6 shows a preferred exemplary embodiment of a carrier; and

FIG. 7 shows a schematic section of the device with the carrier of FIG. 6.

### DETAILED DESCRIPTION OF THE INVENTION

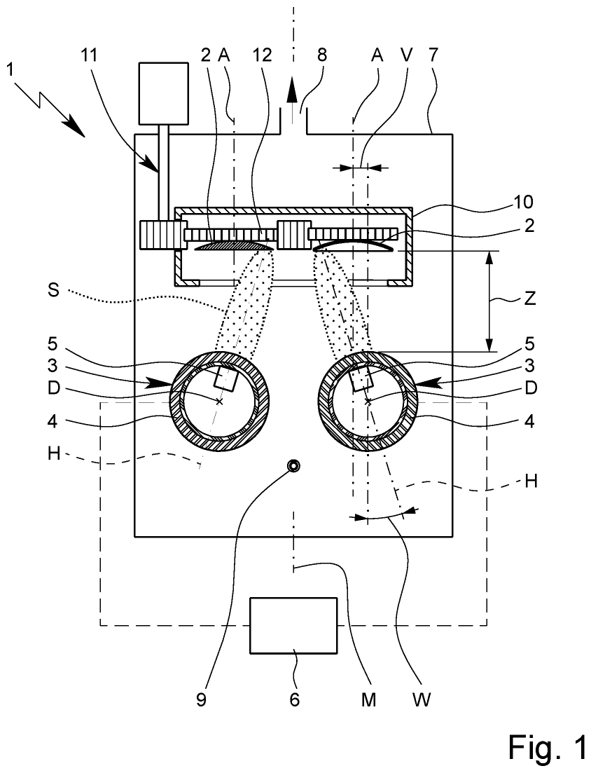

FIG. 1 shows in a very schematic section a device 1 according to the proposal for coating of lenses 2, preferably optical or ophthalmic lenses and/or eyeglass lenses, in particular of plastic.

The device 1 is designed in particular for coating of lenses 2 by sputtering, also called cathode sputtering. Especially preferably, so-called magnetron sputtering takes place. In addition to an electrically applied field, in doing so, a magnetic field is also used and/or applied; this will be explained in detail below.

Especially preferably, curved, in particular concave surfaces of the lenses 2 are coated according to the invention. One such curved surface is schematically indicated in FIG. 1 for the lens 2 which is shown on the right side. However, in principle convex surfaces or other surfaces of the lenses 2 can also be coated accordingly.

The device 1 has at least one sputtering source 3, here preferably two sputtering sources 3.

The device 1 or the respective sputtering source 3 has one target 4 whose material is removed during coating and/or sputtering and—in particular together with the other components of the gas atmosphere—forms the desired coating on the respective lens 2 or its surface which is to be coated.

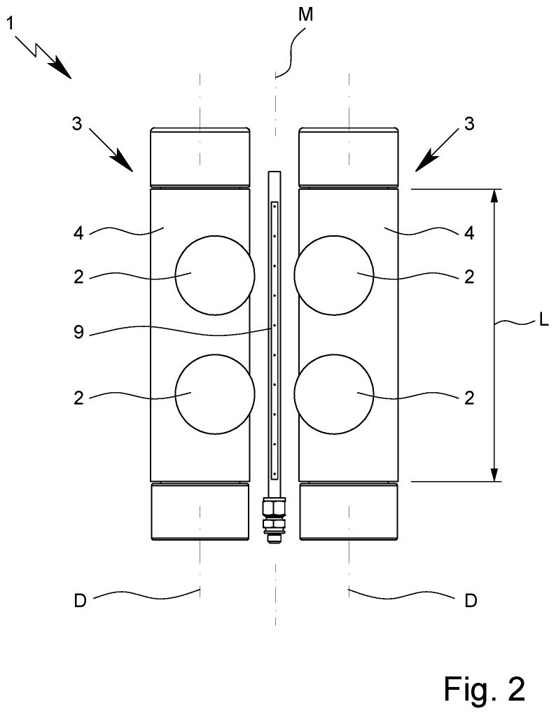

FIG. 2 shows the device 1 or sputtering sources 3 in a schematic plan view.

The sputtering sources 3 and/or targets 4 in the illustrated example are preferably made at least essentially elongated and/or tubular or cylindrical.

The targets 4 are made in particular hollow cylindrical and/or tubular.

The sputtering sources 3 and/or targets 4 are preferably arranged parallel to one another.

Preferably, the targets 4 can be turned or rotated around the axes D of rotation. The axes D of rotation run preferably in one common plane and/or in particular parallel to one another, as indicated in FIGS. 1 and 2, but alternatively can also be tilted to one another. The axes D of rotation correspond preferably to the longitudinal axes of the sputtering sources 3.

Especially preferably, the sputtering sources 3 and/or targets 4 are structurally identical and/or are built identically so that primarily only the structure of one sputtering source 3 and/or one target 4 is detailed below. However, the sputtering sources 3 and targets 4 can in principle also be made differently.

The sputtering source 3 has preferably one magnet arrangement 5 which is assigned to the respective target 4 for generating the already mentioned magnetic field and thus to a directed sputtering cloud S, as schematically indicated in FIG. 1. In particular, the magnet arrangement 5 is located under and/or in the respective target 4.

The device 1 has a voltage source 6, as indicated in FIG. 1, in order to operate the sputtering sources 3 and/or targets 4—in particular alternately—as a cathode and/or in order to be able to apply the required voltage to the sputtering sources 3 and/or targets 4 for sputtering, in particular in the form of pulses.

Especially preferably, the sputtering sources 3 and/or targets 4 are operated and/or exposed alternately with direct current (pulses). This is also called “bipolar DC”. Alternately then one sputtering source 3 and/or target 4 is used as the cathode and the other sputtering source 3 and/or the other target 4 as the anode.

Alternatively, operation with alternating current or some other mode are possible.

Alternatively, or in addition, one or more additional or separate anodes can be used, even if this is not preferred.

The device 1 has preferably one coating chamber 7 in which the coating takes place and/or the sputtering sources 3 are located.

The preferred alternating operation of the sputtering sources 3 and/or targets 4 as cathode and anode leads to a housing-side or fixed counter-electrode not being necessary. In particular, the coating chamber 7 is not used as a counter-electrode. In this way, unwanted soiling and/or deposition of target material on the counter-electrode can be minimized and/or an especially stable method or coating can also be achieved regardless of soiling of the coating chamber 7. Accordingly, in this way required cleanings and maintenances can be reduced.

Furthermore, the targets 4 can be very easily changed. This also facilitates service.

The coating chamber 7 can be evacuated in the desired manner in particular by means of an apparatus 8 which is indicated only schematically here, such as a connection, a vacuum pump or the like.

The device 1 and/or the coating chamber 7 preferably has a schematically indicated gas supply 9, in particular in the form of a gas lance which extends into the coating space.

The device 1 has preferably one carrier 10 for holding the lenses 2, as indicated in FIG. 1.

The carrier 10 is not shown in FIG. 2 and in other figures for purposes of illustration.

The lenses 2 which are to be coated can preferably each be turned or rotated around an axis A. The device 1 and/or the carrier 10 is designed for corresponding rotary holding and in particular for corresponding driving of the lenses 2. In particular, the device 1 has a corresponding rotary drive 11 which is only schematically indicated in FIG. 1, preferably in order to drive all lenses 2 of the carrier 10 jointly.

Preferably, the carrier 10 is interchangeable together with at least two lenses 2 or all lenses 2 or here four lenses 2 which are being coated at the same time in the device 1 and/or the coating chamber 7.

In particular, the carrier 10 holds the lenses 2 such that they can be rotated—in particular around their own and/or different axes A—, especially preferably such that they are rotatably coupled. Especially preferably, the carrier 10 has a rotary coupling 12, for example via a corresponding gear, as schematically indicated in FIG. 1.

Preferably, the carrier 10 itself is not moved during the coating, but only the lenses 2 held by the carrier 10 are rotated. Preferably, the carrier 10 can be automatically coupled drivingly or by transmission or coupled in terms of drive or gear, in particular to the rotary drive 11 or the like of the device 1, upon insertion of the carrier 10 or pushing the carrier 10 into the device 1 and/or coating chamber 7.

The carrier 10 allows quick feed of the device 1 and/or the coating chamber 7 with the lenses 2 which are to be coated and/or quick removal of the coated lenses 2.

The device 1 and/or coating chamber 7 can preferably be fed with the lenses 2 to be coated and the carrier 10 via an access opening 7A which is not shown in FIG. 1. The access opening 7A can be sealed in particular gas-tight preferably by means of the carrier 10 or by a closure which is not shown.

The coating chamber 7 can preferably be sealed gas-tight for coating.

The carrier 10 can preferably be used in general in devices for the coating of lenses 2, in particular therefore also in coating methods other than sputtering.

The axes D of rotation and/or longitudinal extensions L of the target 4 run preferably in a common plane, especially preferably a horizontal plane.

The lenses 2 are preferably located above the aforementioned plane.

Preferably, each lens 2 is located over an assigned target 4. The term “over” can relate to the vertical height relative to the assigned target 4 and/or to the surface of the lens 2 to be coated having at least one surface normal which intersects the target 4 and especially preferably its axis D of rotation.

Preferably, the lenses 2 are assigned in pairs to one sputtering source 3 and/or one target 4.

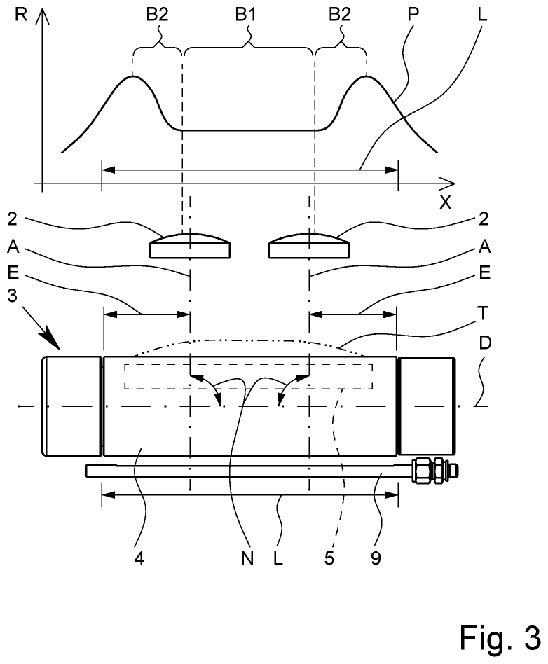

In particular, two lenses 2 are located above a common target 4 in each case, as indicated in FIG. 2 and in the schematic side view according to FIG. 3.

Especially preferably, the device 1 and/or the carrier 10 is designed for accommodating two pairs of lenses 2, therefore a total of four lenses 2, two lenses 2 being assigned to a common sputtering source 3 and/or a common target 4 in each case. The preferred arrangement and alignment of one such pair of lenses 2 which are assigned to a common target 4 are detailed below. These statements and explanations apply in particular accordingly to the other pair of lenses 2 since the device 1 and/or the arrangement of lenses 2 in the device 1 is especially preferably for the most part symmetrical with respect to a middle plane M—in FIGS. 1 and 2 the middle plane M which is standing vertically on the plane of the drawing.

The lenses 2 which are assigned to a common target 4 are preferably arranged offset in one direction parallel to the longitudinal extension L and/or axis D of rotation of the target 4. This direction is also called the X direction or X axis in particular in the diagram schematically indicated in FIG. 3.

The lenses 2 and/or their axes A are arranged preferably symmetrically with respect to the longitudinal extension L of the target 4 and/or have an offset or distance E from the respective end of the target 4 in the axial direction or X direction.

In particular, the lenses 2 are located in an end region or its vicinity of the respective target 4, as indicated in FIGS. 1 and 2.

The diagram in FIG. 3 qualitatively illustrates the rate R of removal of the target 4 during coating as a function of the axial position or X position. In this way a rate profile P of the rate R over X, therefore in the direction of the longitudinal extension L of the target 4, arises.

The rate profile P has a first at least essentially homogeneous region B1 in the middle axial region of the target 4 homogeneous. The rate R in the first region B1 is thus at least essentially constant and/or varies along the axial extension of the target 4 in this region B1 at best only very little, in particular less than 5%. Preferably, “essentially constant” according to the invention means that the rate R along the longitudinal axis L, here in the region B1, varies by less than 5%.

The rate profile P furthermore has a second, non-homogeneous or inhomogeneous region B2. In this second region B2 the rate R varies very strongly, increases strongly in particular towards the end of the target 4, especially preferably by more than 10%.

The rate R of removal of the target 4 which increases towards the end of the target 4 and/or the respective magnet arrangement 5 in the second region B2 can be explained by the magnetic field strength which is increased in the end region.

FIG. 3 shows that a second region B2 in the indicated sense adjoins the first region B1 on both sides and/or towards the respective end of the target 4.

The lenses 2 are preferably each arranged—here in the axial extension L and/or X direction over the target 4—such that the lens 2 is located both in the first region B1 and in the second region B2 or overlaps them. Especially preferably, the middle and/or axis A of the respective lens 2 is located in the vicinity of the transition from the first region B1 to the second region B2. The deviation of the axis A from this transition is preferably less than 30%, in particular less than 20%, especially preferably less than 10% of the lens diameter.

It has been shown that the aforementioned arrangement of the lens 2 both in the first region B1 and in the second region B2 in consideration of the rotation of the lens 2 around the axis A during coating can yield an especially uniform coating.

The axis A around which the lens 2 rotates during coating is preferably stationary or fixed relative to the target 4 or the sputtering source 3 or axis D of rotation.

In particular, a linear movement and/or a center-of-gravity movement such as a circular movement between the sputtering source 3 and/or the target 4 and/or the axes D of rotation on the one hand and the lens 2 or lenses 2 to be coated and/or the axes A on the other is avoided or precluded. This is conducive to an especially simple structure.

The offset or distance E of the axis A of rotation of the lens 2 from the respective end of the target 4 is preferably more than 1.0 times or 1.5 times the lens diameter and/or the target diameter.

The distance E is preferably fixed. Optionally, an adaptation or adjustment of the distance E of the axis A of rotation of the lens 2 from the respective end of the target 4 takes place as a function of the diameter and/or the curvature and/or shape of the lens 2 or surface which is to be coated.

The (vertical) distance Z of the lens 2 from the assigned target 4 is indicated in FIG. 1 and is preferably more than 1.0 times the lens diameter or the target diameter.

The (vertical) distance Z of the lens 2 from the assigned target 4 is preferably more than 60 mm and/or less than 150 mm, in particular less than 130 mm.

The distance Z is preferably fixed. Optionally, an adaptation or adjustment of the (vertical) distance Z of the lens 2 from the assigned target 4 takes place as a function of the diameter and/or the curvature and/or shape of the lens 2 or surface which is to be coated.

The target diameter is preferably about 70 to 130 mm.

Preferably, the (outside) diameter of the target is at least essentially constant over the length.

The target 4 is thus preferably made cylindrical or hollow cylindrical.

The axes A of two lenses 2 which are assigned to a common target 4 run preferably in one common plane and in particular parallel to one another.

The axes A run preferably transversely or perpendicular to the target plane and/or common plane of the axes D of rotation and/or to the axis D of rotation of the assigned target 4.

In their common plane the axes A can also be inclined relative to one another, in particular at one another or to the outside or away from one another. Accordingly, the lenses 2 are then brought closer to one another or moved away from one another, in particular optionally so that the surfaces to be coated of the two lenses 2 are somewhat tilted towards one another and/or point somewhat more towards the middle of the respective target 4. Accordingly, the angle N of incline of the axes A to the axes D of rotation can deviate from the preferred 90°, as shown in FIG. 3, and can be less than 90°, for example about 70° to 85°, or more than 90°, for example about 95° to 110°.

The angle N of incline is preferably fixed. Especially preferably, however, an adaptation or adjustment of the angle N of incline optionally takes place as a function of the diameter and/or the curvature and/or shape of the lens 2 or surface which is to be coated.

The axis A of rotation of the lens 2 can also be shifted in the Y direction, thus in a direction transversely to the axis D of rotation in the horizontal direction and/or towards the middle between the two axes D of rotation of the targets 4, in particular so that an offset or distance V forms between the lens axis A and the assigned target axis D, as indicated in FIG. 1 for the lens 2 which is located on the right side (of course the same also applies preferably to the lens 2 which is located on the left side). The offset or distance V is preferably less than 20%, in particular less than 10%, of the lens diameter and/or target diameter.

The distance V is preferably fixed. Optionally, an adaptation or adjustment of the distance V between the lens axis A and the assigned target axis D takes place as a function of the diameter and/or the curvature and/or shape of the lens 2 or surface which is to be coated.

Preferably the angle N of incline and/or the location of the axes A or the distances E, V and/or Z are established by the carrier 10.

The gas supply 9 is preferably located underneath the sputtering sources 3 and/or targets 4 and/or in between, especially preferably in the middle plane M of the device 1 and/or coating chamber 7.

The gas supply 9 is preferably designed tubular and/or rod-like and/or is provided with gas outlets which point up and/or which are located preferably in a row.

The sputtering cloud S which arises during coating, i.e. the sputtered target material, is guided at least essentially in a desired direction by means of the already mentioned magnetic field and/or the magnet arrangement 5 in each case. This primary direction H of propagation of the sputtering cloud S which is indicated by the broken line in FIG. 1 can be influenced, in particular can be established, by corresponding arrangement or orientation of the magnet arrangement 5.

In the illustrated example, the primary direction H in the plane of the section perpendicular to the axes D of rotation and/or of the two targets 4 is preferably tilted to one another and/or by the angle W (starting from a parallel orientation). Preferably, the angle W can be set or adapted, in particular by corresponding adjustment or triggering of the magnet arrangements 5.

The angle W is preferably less than 10°, in particular less than 7°, especially preferably less than 5°.

As already indicated, the primary directions H of the two sputtering clouds S can also run parallel to one another and/or perpendicular to the extension plane of the target 4 and/or plane with the axes D of rotation.

Preferably, the primary directions H run vertically upward or contain one such direction component. Alternatively, there is a horizontal alignment of the primary directions H. The arrangement of the lenses 2 and sputtering sources 3 and/or targets 4 must then be chosen of course accordingly.

Preferably, the lenses 2 in the device 1 according to the proposal and in the method according to the proposal are each held both in the first region B1 and in the second region B2 and rotated in doing so. This can yield an especially uniform coating.

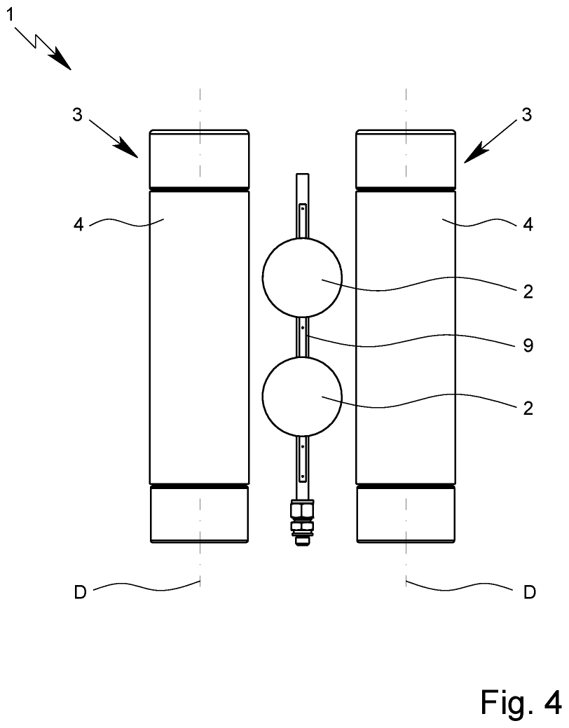

Especially preferably, the lenses 2 are coated in pairs, in particular two pairs of lenses 2 are coated at the same time. However, it is in principle also possible to coat only one pair of lenses 2 in the device 1 according to the proposal. To do this, the two lenses are then located preferably over a common target 4 and/or between the two targets 4, as shown schematically in FIG. 4 in one alternative arrangement.

Preferably, the rate profile P is not influenced or homogenized by distribution diaphragms or the like in the device 1 and/or coating chamber 7. This is advantageous in particular with respect to unwanted deposits on such diaphragms.

According to one aspect of the present invention which can also be implemented independently the outside diameter of the target 4 can vary over the axial extension or length or the longitudinal extension L of the target 4, as indicated schematically in FIG. 3 by the double-dotted broken line or target surface T.

In particular, the target 4 can be made for example thicker in the middle than on the end regions and/or for example barrel-shaped.

In the middle and/or between the axes A of rotation of the lenses 2 and/or between the regions B2 (which are forming otherwise) the outside diameter of the target 4 is preferably at least essentially constant and/or for example more than 4% larger than on the ends of the target 4, as indicated in FIG. 3.

In particular, the outside diameter can also be reduced or can decrease only towards the end regions of the target 4, in particular in the regions B2 and/or only in the end region by less than 25% of the length L of the target 4.

In principle, the outside diameter in the longitudinal extension L can have any shape, if necessary also (partially) convex, concave or corrugated.

Preferably, the outside diameter of the target 4 varies by more than 4% over the longitudinal extension or length L of the target 4.

Especially preferably, the rate profile P is modified in the desired manner, for example made (more) uniform, by variation of the outside diameter over the length L of the target 4.

Alternatively or in addition to the variation of the outside diameter, the magnetic field and/or the magnetic field strength of the magnet arrangement 5 can also vary over the length L of the target 4 and/or of the sputtering source 3, in particular can decrease towards the end and/or can be greater in the region of the middle, in particular by more than 4%, in order to modify the rate profile P in the desired manner, especially preferably to make it (more) uniform, and/or to achieve a certain or desired and/or at least essentially constant strength of the magnetic field on the target surface, in particular also in consideration of the optionally varying outside diameter, even when the outside diameter of the target 4 varies.

The aforementioned variations of the outside diameter and/or magnetic field preferably make the rate profile P (more) uniform, modifies or fixes it such that in particular in consideration of the positioning of the lens 2 to be coated relative to the target 4 (for example the location of the axis A of rotation of the lens 2 and the distance of the lens 2) and/or in consideration of the shape and/or the size of the surface of the lens 2 which is to be coated, a desired coating of the lens 2 can be achieved or is achieved, which coating is in particular uniform or defined in some other manner, or which coating is optionally also nonuniform, for example increases or decreases towards the edge.

The lenses 2 rotate preferably centrically around the respective axis A, in particular with respect to the geometrical center of the lens 2.

According to one version which is not shown, the lenses 2 can optionally also rotate and/or be clamped eccentrically with respect to the axis A of rotation. The eccentricity is here preferably smaller than the radius of the lens 2, and can optionally also be larger.

In particular, the axis A of rotation thus intersects the respective lens 2.

The axis A runs preferably perpendicular to the main plane of the respective lens 2.

Each of the lenses 2 can preferably be rotated around its own axis A.

The axis A runs preferably transversely, optionally perpendicular, to the longitudinal extension or axis D of rotation of the assigned target 4.

In particular, the axis A of rotation of the respective lens 2 intersects the assigned target 4, as indicated in FIG. 1, or optionally, the longitudinal axis or axis D of rotation of the assigned target 4.

The lens 2 during coating and/or rotation preferably always points toward the assigned target 4 or the two assigned targets 4 with its side to be coated.

Preferably, the axis D of rotation of the respective target 4 runs perpendicular to any or at least one surface normal of the lens 2 or surface which is to be coated.

The surface normal of the optical or geometrical center of the lens 2 can be tilted to the axis A of rotation or axis D of rotation.

The lens centers are preferably arranged symmetrically to the respective target 4 in the X direction and/or longitudinal extension of the target 4.

The lenses 2 which are to be coated and/or their geometrical or optical centers are preferably arranged at least essentially in a common plane, this plane running especially preferably parallel to the extension plane of the sputtering sources 3 and/or targets 4 or axes D of rotation.

With the device 1 according to the proposal and/or the method according to the proposal or the use of tubular parallel targets 4 according to the proposal for coating of lenses 2, preferably coating rates from 0.001 to 20 nm/s, in particular 0.005 nm/s to 2.5 nm/s, are achieved.

The rotational velocity of the lenses 2 is preferably 10 to 200 rpm, in particular about 40 to 120 rpm.

The diameter of the lenses 2 is preferably about 40 to 85 mm.

The rotational velocity of the target 4 is preferably about 3 to 30 rpm.

Preferably, the rotational velocity of the lenses 2 is greater than that of the target 4, in particular it is more than 2 or 3 times the rotational velocity of the target 4.

The coating time is preferably about 4 to 7 min.

The device 1 according to the proposal or the method according to the proposal or the use according to the proposal is preferably used to apply one or more antireflection layers.

According to the proposal, in particular reactive coating takes place, wherein by corresponding supply of reactive gas, for example nitrogen, hydrogen and/or oxygen, to the working gas (noble gas), in particular argon, the target material is able to react with it and a desired coating on the lens 2 can form.

During coating, the device 1 and/or the coating chamber 7 is preferably evacuated to a pressure of about 0.005 Pa to 0.5 Pa.

In particular, a device 1 and methods for coating of lenses 2 are proposed, wherein lenses to be coated are arranged in pairs over parallel tubular targets 4 such that they each overlap both a homogeneous and an inhomogeneous removal region B1, B2 of the target 4 and wherein the lenses 2 rotate so that an especially uniform coating can be achieved.

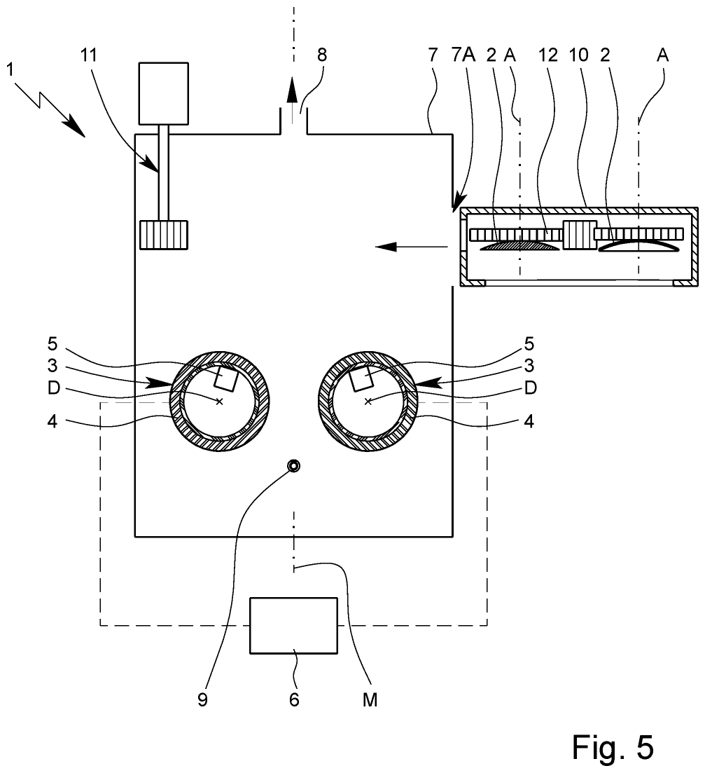

FIG. 5 shows the insertion of the carrier 10 into the device 1 or coating chamber 7. Here, the access opening 7A through which the carrier 10 is inserted or insertable is shown. As already mentioned above, the access opening 7A can be sealed in particular gas-tight preferably by means of the carrier 10 or by a closure which is not shown.

The carrier 10 can be removed again from the device 1 or coating chamber 7, in particular via the access opening 7A or a different opening, preferably after coating. When the carrier 10 with the coated lenses 2 has been removed, a new carrier with lenses to be coated can be inserted.

Particularly preferably, the access opening 7A and an opening opposite the access opening 7A are provided. In this case, the carrier 10 preferably enters the device 1 or coating chamber 7 exclusively via the access opening 7A and leaves the device 1 or coating chamber 7 exclusively via the opening opposite the access opening 7A. In this case, the rotary drive 11 is located preferably centrally or at a side allowing the desired movement of the carrier 10.

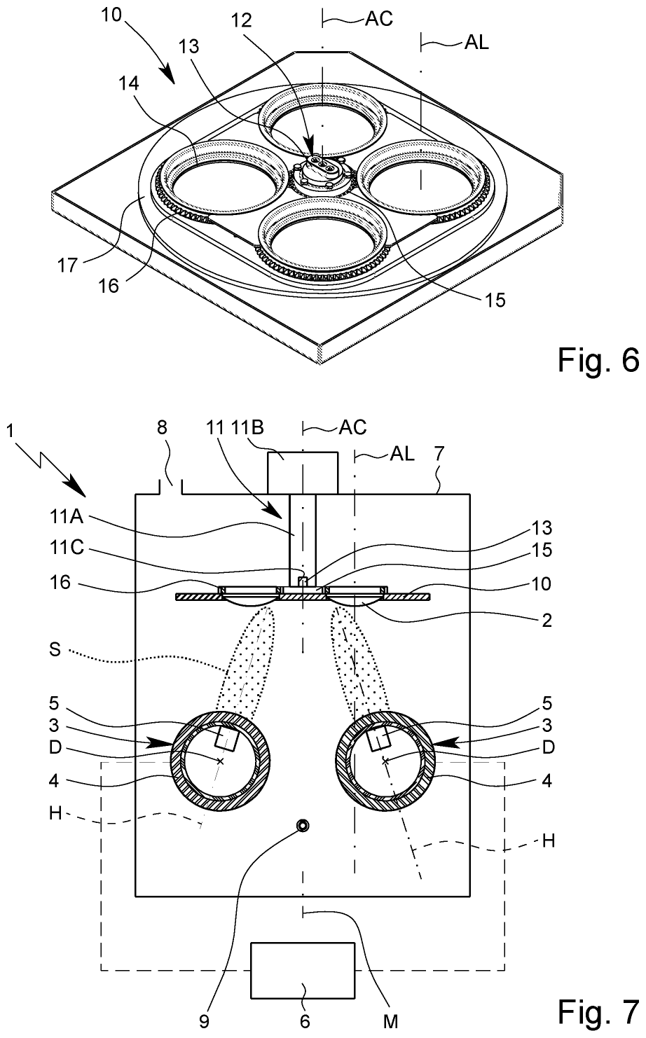

FIG. 6 shows a preferred further embodiment of the carrier 10. FIG. 7 shows in a schematic section corresponding to FIG. 1 a preferred further embodiment of the device 1 with the carrier 10 of FIG. 6. All features and explanations described above in connection with FIGS. 1 to 5 preferably apply correspondingly or in addition, unless otherwise stated, even if not explicitly repeated.

The carrier 10 shown in FIG. 6 has the rotary coupling 12 for rotating the lenses 2.

The carrier 10 or rotary coupling 12 comprises a driven element or connection element 13 for connection with the rotary drive 11. The connection element 13 is preferably arranged on a flat surface of the carrier 10 and/or centrally.

A central axis AC runs preferably through the center of the carrier 10 and/or rotary coupling 12 and/or connection element 13, in particular orthogonally to the flat or main surface of the carrier 10 and/or lenses 2.

Lens receptacles 14 are arranged or distributed around the connection element 13 and/or the central axis AC of the carrier 10. In the shown example, four lens receptacles 14 are provided. However, other solutions are possible with more or less lens receptacles 14.

Each of the lens receptacles 14 has preferably its own axis AL. The axes AL preferably run centrally and/or orthogonally through the respective lens receptacles 14. The axis AL is preferably also the center axis or symmetry axis of a lens 2 received in the lens receptacle 14.

The lenses 2 are preferably held or supported in/by the lens receptacles 14 directly or indirectly. In the latter case, each lens 2 may be held by a holding element, in particular a clamping ring, and is inserted or insertable into the respective lens receptacle 14 together with the holding element.

The connection element 13 is preferably rotatable about the central axis AC. The lenses 2 or lens receptacles 14 are preferably rotatable about their respective axes AL.

The connection element 13 is motionally or rotationally coupled to the lens receptacles 14 and/or lenses 2 such that a rotary motion of the connection element 13, in particular about the central axis AC, causes a rotary motion of the lenses 2 and/or the lens receptacles 14, in particular about their respective axes AL.

In addition to the rotation about their axes AL, the lenses 2 and/or lens receptacles 14 may also rotate or be rotatable about the central axis AC. Thus, each lens 2 or lens receptacle 14 may perform a motion which corresponds to two superposed rotary motions, namely a first rotary motion about the central axis AC and a second rotary motion about the respective axis AL. In that case, the axes AL are not fixed or stationary, but rotate about the central axis AC as well.

However, it is also possible that the axes AL are fixed or stationary with respect to the central axis AC. In that case, the lenses 2 and/or lens receptacles 14 only rotate about their respective axes AL, but not about the central axis AC.

In the following, preferred exemplary embodiments of the rotary coupling 12 are described, i.e., how rotation of the connection element 13 is transferred/converted to rotation of the lenses 2 about their axes AL and optionally the axis AC.

The carrier 10 or rotary coupling 12 preferably comprises a gear arrangement or the rotary coupling 12 is preferably realized via a gear arrangement.

The carrier 10, rotary coupling 12 or gear arrangement preferably comprises a central wheel or central gear 15, also referred to as sun wheel or sun gear. The central gear 15 is arranged centrally on the carrier 10 and/or symmetrically to the central axis AC and/or below or around the connection element 13.

Preferably, each lens receptacle 14 is provided with a toothing or lens receptacle gear 16, in particular on the circumference of the respective lens receptacle 14. Particularly preferably, the lens receptacle gear 16 is a toothed ring surrounding the lens receptacle 14.

Each lens receptacle gear 16 engages or meshes with the central gear 15, in particular exclusively with the central gear 15.

Preferably, the number of teeth of the central gear 15 is smaller than the number of teeth of each of the lens receptacle gears 16. The gear ratio is preferably about 1:2 to 1:3 or 1:4

In one exemplary embodiment, the central gear 15 is rotatable about the central axis AC. A rotary motion of the connection element 13 causes a rotary motion of the central gear 15. Preferably, the connection element 13 and central gear 15 are integrally formed or rigidly connected with each other.

Since the central gear 15 meshes with the lens receptacle gears 16, a rotary motion of the central gear 15 causes the lens receptacle gears 16 and thus the lens receptacles 14 and/or lenses 2 to rotate about their respective axes AL.

In another exemplary embodiment, the central gear 15 is fixed or secured against rotation. In this embodiment, the connection element 13 is rigidly connected with a turntable 17. Rotation of the connection element 13 about the central axis AC causes a rotation of the turntable 17 about the central axis AC. Since the lenses 2 or lens receptacles 14 are arranged on the turntable 17, they rotate about the central axis AC as well.

While the lens receptacle gears 16 rotate about the axis AC, their meshing with the stationary/fixed central gear 15 causes them to rotate about their respective axes AL in addition. Thus, in this embodiment, the lenses 2 or lens receptacles 14 rotate both about the central axis AC and their respective axes AL.

The above-described embodiments of the rotary coupling 12 are only exemplary. Other solutions to transfer a rotary motion of the connection element 13 to rotary motions of the lenses 2 are possible as well.

In the following, the coupling of the rotary drive 11 with the carrier 10 for driving the lens rotation is explained in more detail.

As shown in FIG. 7, the rotary drive 11 of the device 1 is preferably arranged symmetrically to the middle plane M.

The rotary drive 11 preferably comprises a driving element or shaft 11A and/or a motor 11B. The shaft 11A is preferably rotatable about its symmetry axis and/or rotatably driven by the motor 11B.

The rotary drive 11, in particular the driving element or shaft 11A, preferably drives, connects and/or engages the carrier 10 or the rotary coupling 12, in particular the connection element 13, from above and/or at its center.

Particularly preferably, in the connected state or coupled state in which the rotary drive 11 and the carrier 10 are connected/coupled with each other, the symmetry axis or rotation axis of the shaft 11A coincides with the central axis AC of the carrier 10.

The rotary drive 11 or shaft 11A preferably comprises a connection portion 11C that releasably connects with the carrier 10 or rotary coupling 12, in particular with the connection element 13. The connection portion 11C and the connection element 13 are preferably complementary to each other.

In the connected/coupled state shown in FIG. 7, the connection portion 11C and the connection element 13 are engaged with each other in a form-fitting manner. In particular, due to the engagement, a rotation of the rotary drive 11 or shaft 11A causes a rotation of the connection element 13, and in turn of the lenses 2 via the rotary coupling 12.

In the exemplary embodiment shown in FIG. 7, the connection portion 11C is an opening, indentation, recess, notch, groove or slot, in particular at an axial end face of the shaft 11A.

The connection element 13 preferably matches the form of the connection portion 11C. In the exemplary embodiment shown in FIGS. 6 and 7, the connection element 13 is elongated and or formed as a ridge, ledge, web, elevation or protrusion.

However, other solutions are also possible. For example, the construction could be reversed such that the connection portion 11C is formed as an elevation, ridge or the like, in particular at an axial end face of the shaft 11A, and the connection element 13 is formed as a complementary indentation, notch or the like.

When the carrier 10 is inserted into the device 1 or coating chamber 7, the connection element 13 enters or slides into the connection portion 11C, in particular in the longitudinal direction of the connection portion 11C and/or the direction of longitudinal extension of the connection element 13 and/or orthogonally to the rotation axis of the rotary drive 11 and/or central axis AC of the carrier 10. Thus, in FIG. 7, the carrier 10 is inserted into or enters the device 1 or coating chamber 7 in a direction perpendicular to the drawing plane.

The connection element 13 may be beveled or chamfered or rounded to make entry into the connection portion 11C easier or self-centering. FIG. 6 shows exemplary a connection element 13 which is rounded at its edges. Alternatively or in addition, the connection portion 11C may be beveled or chamfered or tapered toward the inside to make entry of the connection element 13 into the connection portion 11C easier or self-centering.

The rotary coupling 12 or rotating of the connection element 13 is preferably self-impeding and/or stiff and/or sluggish such that the connection element 13 is or remains in a defined rotational position when/for entering or sliding into or engaging the connection portion 11C.

During coating, the rotary drive 11, in particular the shaft 11A, rotates and thereby drives the rotary coupling 12, in particular via the connection element 13, such that the lenses 2 rotate at least around their respective axes AL and optionally also around the central axis AC.

After the coating process is finished, the rotary drive 11, in particular the shaft 11A, stops rotation in a defined rotational manner, preferably in the same or opposite orientation as when the carrier 10 entered. The connection element 13 then disengages or slides out of the connection portion 11C, preferably in the same or the opposite direction as when engaging with the connection portion 11C, and the carrier 10 with the coated lenses 2 exits the device 1 or coating chamber 7, preferably in the same or the opposite direction as when being inserted into or entering the device 1 or coating chamber 7.

A preferred aspect, which can also be implemented independently, is a device 1 for the coating of lenses comprising a rotary drive 11 that releasably engages with a carrier 10 holding a plurality of lenses 2, the rotary drive 11 engaging or driving the carrier 10 at its center and/or from above, in particular such that the rotation axis of the rotary drive 11 coincides with the central axis AC of the carrier 10.

A preferred aspect, which can also be implemented independently, is a method for the coating of lenses comprising a carrier 10 holding a plurality of lenses 2 to be coated sliding into releasable engagement with a rotary drive 11 in a direction orthogonally to the rotation axis of the rotary drive 11, the rotary drive 11 releasably engaging the carrier 10 at its center and/or from above, in particular such that the rotation axis of the rotary drive 11 coincides with the central axis AC of the carrier 10.

The method preferably further comprises during coating, the rotary drive 11 driving a lens rotation mechanism of the carrier 10 via the central connection between the rotary drive 11 and the carrier 10, the lenses 2 rotating during coating about axes AL which intersect and/or are central to the respective lenses 2 and the lenses optionally rotating during coating about the central axis AC of the carrier 10.

The method preferably further comprises after coating, the carrier 10 disengaging or sliding out of the rotary drive 11 in the same or opposite direction as when it engaged or slid into the rotary drive 11.

What is claimed is:

1. A method for coating of lenses in a coating device by means of sputtering, comprising:
holding at least one lens to be coated on a carrier that enables the lens to be rotatable on the carrier around an axis which intersects with the lens,
arranging the lens relative to at least one tubular target both in a first region of the target from which removal of material from the target will be at least essentially homogeneous in a longitudinal extension of the target, a rate of the removal during coating varying by less than 5%, and in a second region of the target from which removal of material from the target during coating will be inhomogeneous in the longitudinal extension of the target, and
producing coating of the lens by sputtering from at least one tubular target with the lens being rotated around a stationary axis relative to the target.

2. The method according to claim 1, wherein said at least one lens is at least two lenses that are held on the carrier in a manner enabling the at least two lenses to be changed at the same time.

3. The method according to claim 1, comprising the further step of positioning the at least one lens on the carrier so as to be located over the target off-center relative to the longitudinal extension of the target.

4. The method according to claim 1, comprising the further step of holding the lens on the carrier in a position that is stationary relative to the longitudinal extension of the target.

5. The method according to claim 1, comprising the further step of positioning two lenses symmetrically with respect to the longitudinal extension of the target.

6. The method according to claim 1, wherein the carrier holds two lenses over opposite end regions of the target.

7. The method according to claim 1, comprising the further step of rotating the target during coating.

8. The method according to claim 1, wherein said at least one tubular target comprises two tubular targets which run parallel to one another, and wherein the targets are operated alternately as a cathode and an anode.

9. The method according to claim 8, comprising the further step of arranging four lenses over the targets, two lenses over each of the two targets.

10. The method according to claim 8, wherein the axes of the lenses are positioned to run transversely to a common plane of the targets.

11. The method according to claim 1, comprising the further step holding a plurality of lenses on the carrier rotatably coupled.

12. The method according to claim 1, wherein a plurality of lenses are held on the carrier each of which are rotated around a respective axis.

13. The method according to claim 1, further comprising the step of automatically coupling a transmission of the carrier to a rotary drive of the coating device when the carrier is inserted into the coating device.

14. The method according to claim 1, wherein the carrier holds the lens with at least one of a stationary center of gravity and in a centrically rotatable manner

15. The method according to claim 1, comprising the further step of positioning the axis of the lens so that it intersects with the target.

16. A method for coating of lenses by means of sputtering, comprising:
mounting of at least two lenses to be coated on a carrier in a manner enabling each one of the at least two lenses to be rotatable, by a rotary coupling located within the carrier, around a respective axis of rotation which intersects with the respective one of the at least two lenses,
removably inserting the carrier with the lenses into a coating device having at least one tubular target and a drive for rotating the lenses via the rotary coupling of the carrier, and creating a drive connection between the drive of the coating device and the rotary coupling for enabling rotation of the lenses within the carrier,
producing sputtering of material from at least one tubular target with the lenses positioned transversely offset relative a longitudinal axis of tubular targets, and
removing the carrier with the lenses from the coating device after the lenses have been coated.

17. The method according to claim 16, comprising the further step of holding the respective axis of the at least two lenses in a stationary position relative to a longitudinal axis of the at least one tubular target during sputtering.

18. The method according to claim 16, comprising the further step of rotating the lenses about the respective axis during sputtering.

19. The method according to claim 17, comprising the further step of, for said sputtering, arranging the at least one lens relative to the at least one tubular target both in a first region of the target from which removal of material from the target will be at least essentially homogeneous in a longitudinal extension of the target, a rate of the removal during coating varying by less than 5%, and in a second region of the target from which removal of material from the target during coating will be inhomogeneous in the longitudinal extension of the target.

20. The method according to claim 16, comprising the further step of, for said sputtering, arranging the at least one lens relative to the at least one tubular target both in a first region of the target from which removal of material from the target will be at least essentially homogeneous in a longitudinal extension of the target, a rate of the removal during coating varying by less than 5%, and in a second region of the target from which removal of material from the target during coating will be inhomogeneous in the longitudinal extension of the target.
